(19) United States
(12) Patent Application Publication
(10) Pub. No.: US 2022/0418079 A1
(43) Pub. Date: Dec. 29, 2022

(54) INSULATING METAL SUBSTRATE STRUCTURE

(71) Applicant: AMULAIRE THERMAL TECHNOLOGY, INC., New Taipei City (TW)

(72) Inventors: SHIH-HSI TAI, New Taipei City (TW); TZE-YANG YEH, New Taipei City (TW)

(21) Appl. No.: 17/358,150

(22) Filed: Jun. 25, 2021

(51) Int. Cl. H05K 1/02; H05K 1/05

(52) U.S. Cl. CPC H05K 1/0201; H05K 1/056; H05K 1/0306

(57) ABSTRACT

An insulating metal substrate structure is provided. The insulating metal substrate structure includes an electrically-insulating layer, a plurality of metal layers, a plurality of electrically-insulating heat-conductive layers, and a heat-dissipation layer. The plurality of electrically-insulating heat-conductive layers are formed on the heat-dissipation layer. The electrically-insulating layer surrounds the plurality of metal layers, such that the plurality of metal layers are separated into different regions in a different region to form a predetermined circuit pattern. The electrically-insulating layer has at least one recessed corner structure that is configured to position the electrically-insulating heat-conductive layers filled between one of the metal layers and the heat-dissipation layer.

### FIELD OF THE DISCLOSURE

The present disclosure relates to a substrate structure, and more particularly to an insulating metal substrate structure.

### BACKGROUND OF THE DISCLOSURE

Currently, a predetermined circuit pattern of a conventional insulating metal substrate structure is formed through an etching process. Therefore, a manufacturing process of the conventional insulating metal substrate structure is complicated, and a manufacturing cost is high.

### SUMMARY OF THE DISCLOSURE

In response to the above-referenced technical inadequacies, the present disclosure provides an insulating metal substrate structure.

In one aspect, the present disclosure provides an insulating metal substrate structure, which includes an electrically-insulating layer, a plurality of metal layers, a plurality of electrically-insulating heat-conductive layers, and a heat-dissipation layer. The plurality of electrically-insulating heat-conductive layers are formed on the heat-dissipation layer. The electrically-insulating layer surrounds the plurality of metal layers, such that the plurality of metal layers are separated into different regions to form a predetermined circuit pattern. The electrically-insulating layer has at least one recessed corner structure that is configured to position the electrically-insulating heat-conductive layers filled between one of the metal layers and the heat-dissipation layer.

In certain embodiments, the electrically-insulating layer is made from a polymer material having a high bonding property.

In certain embodiments, each of the electrically-insulating heat-conductive layers is made from a polymer material having a high bonding property, and each of the electrically-insulating heat-conductive layers includes a ceramic filler.

In certain embodiments, a thickness of each of the metal layers is less than a thickness of the electrically-insulating layer.

In certain embodiments, each of the metal layers is a copper block having a thickness within a range from 1 mm to 5 mm.

In certain embodiments, the heat-dissipation layer is a metal substrate for heat dissipation.

In certain embodiments, the heat-dissipation layer is a ceramic substrate for heat dissipation and insulation.

In certain embodiments, a bottom portion of the electrically-insulating layer is not in contact with the heat-dissipation layer.

In certain embodiments, a bottom portion of the electrically-insulating layer is directly in contact with the heat-dissipation layer.

Therefore, one of the beneficial effects of the present disclosure is that, in the insulating metal substrate structure provided by the present disclosure, by virtue of “the electrically-insulating layer surrounding the plurality of metal layers such that the plurality of metal layers are separated into different regions to form the predetermined circuit pattern, and the electrically-insulating layer having at least one recessed corner structure that is configured to position the electrically-insulating heat-conductive layers filled between one of the metal layers and the heat-dissipation layer”, the plurality of metal layers can be quickly separated into different regions by the electrically-insulating layer to form the predetermined circuit pattern. In this way, the difficulty of a manufacturing process and a manufacturing cost are reduced, and the electrically-insulating heat-conductive layers filled between one of the metal layers and the heat-dissipation layer can be effectively fixed in position.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a top view of an insulating metal substrate structure according to a first embodiment of the present disclosure;

FIG. 2 is a cross-sectional view taken along line II-II of FIG. 1;

FIG. 3 is a top view of the insulating metal substrate structure according to a second embodiment of the present disclosure; and

FIG. 4 is a cross-sectional view taken along line IV-IV of FIG. 3.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

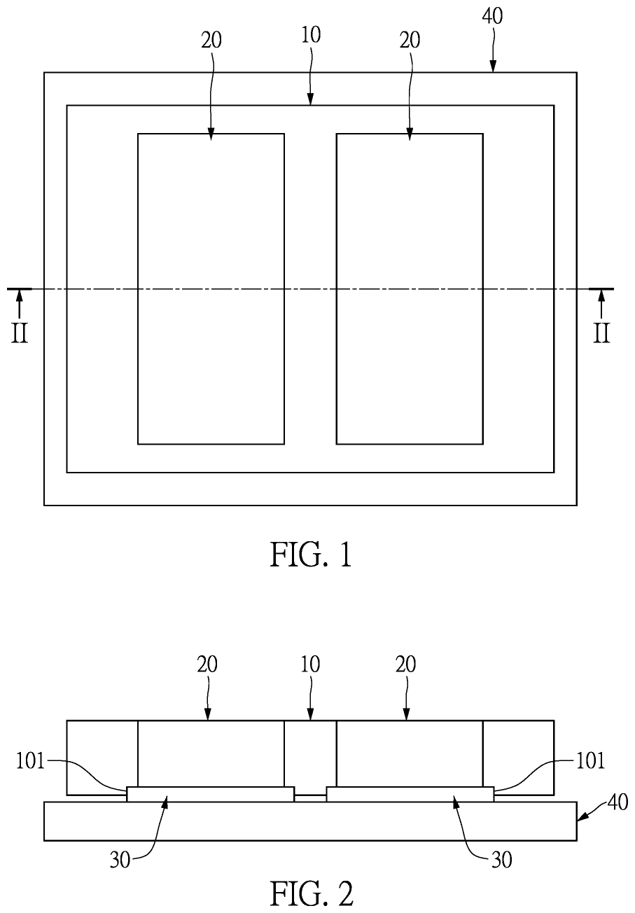

Referring to FIG. 1 and FIG. 2, a first embodiment of the present disclosure provides an insulating metal substrate structure. The insulating metal substrate structure basically includes an electrically-insulating layer 10, a plurality of metal layers 20, a plurality of electrically-insulating heat-conductive layers 30, and a heat-dissipation layer 40.

In the present embodiment, the heat-dissipation layer 40 can be an aluminum heat sink, a heat sink having at least one heat-dissipation fin, a metal substrate for heat dissipation, or a ceramic substrate for heat dissipation and insulation, but the present disclosure is not limited thereto.

In the present embodiment, the plurality of electrically-insulating heat-conductive layers 30 are formed on the heat-dissipation layer 40. Each of the electrically-insulating heat-conductive layers 30 can be made from a polymer material having a high bonding property, such as an epoxy resin, so as to enhance insulation and a bonding property thereof. Further, each of the electrically-insulating heat-conductive layers 30 can include a ceramic filler, so as to increase heat conductivity thereof.

In the present embodiment, a quantity of the plurality of metal layers 20 is two. However, the quantity of the plurality of metal layers 20 is not limited thereto, and can be more than two. The plurality of metal layers 20 are surrounded by the electrically-insulating layer 10, such that the plurality of metal layers 20 are separated into different regions to quickly form a predetermined circuit pattern. The electrically-insulating layer 10 has at least one recessed corner structure 101 configured to position the electrically-insulating heat-conductive layers 30 filled between one of the metal layers 20 and the heat-dissipation layer 40. In this way, the electrically-insulating heat-conductive layers 30 filled between the one of the metal layers 20 and the heat-dissipation layer 40 can be effectively fixed in position.

In the present embodiment, the electrically-insulating layer 10 can be made from a silica gel or a resin. Preferably, the electrically-insulating layer 10 can be made from a polymer material having a high bonding property or an insulation material (such as a ceramic material).

In the present embodiment, each of the metal layers 20 can be a copper block having a thickness within a range from 1 mm to 5 mm. Accordingly, the heat dissipation is more even, and heat conductivity is increased. In addition, the thickness of each of the metal layers 20 is different from a thickness of the electrically-insulating layer 10. The thickness of each of the metal layers 20 is less than the thickness of the electrically-insulating layer 10, such that the electrically-insulating layer 10 can be filled into the plurality of electrically-insulating heat-conductive layers 30 after the plurality of metal layers 20 are surrounded by the electrically-insulating layer 10. A bottom portion of the electrically-insulating layer 10 can be not in contact with the heat-dissipation layer 40.

### Second Embodiment

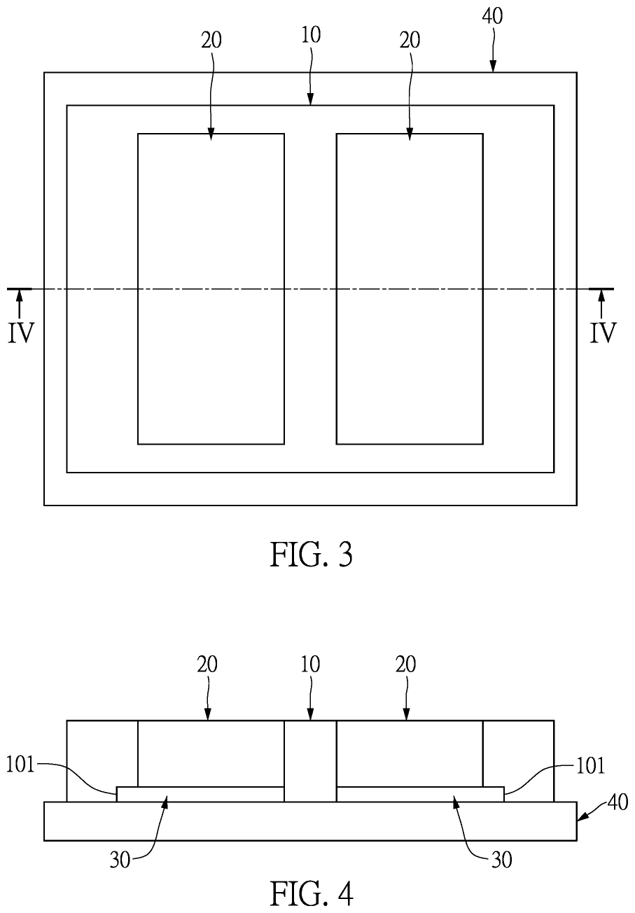

Referring to FIG. 3 and FIG. 4, a second embodiment of the present disclosure provides an insulating metal substrate structure. The insulating metal substrate structure basically includes the electrically-insulating layer 10, the plurality of metal layers 20, the plurality of electrically-insulating heat-conductive layers 30, and the heat-dissipation layer 40.

In the present embodiment, the quantity of the plurality of metal layers 20 is two. However, the quantity of the plurality of metal layers 20 is not limited thereto, and can be more than two. The plurality of metal layers 20 are surrounded by the electrically-insulating layer 10, such that the plurality of metal layers 20 are separated into different regions to quickly form a predetermined circuit pattern. The electrically-insulating layer 10 has at least one recessed corner structure 101 configured to position the electrically-insulating heat-conductive layers 30 filled between one of the metal layers 20 and the heat-dissipation layer 40. In this way, the electrically-insulating heat-conductive layers 30 filled between the one of the metal layers 20 and the heat-dissipation layer 40 can be effectively fixed in position.

The thickness of each of the metal layers 20 is different from the thickness of the electrically-insulating layer 10. The thickness of each of the metal layers 20 is less than the thickness of the electrically-insulating layer 10, such that the electrically-insulating layer 10 can be filled into the plurality of electrically-insulating heat-conductive layers 30 after the plurality of metal layers 20 are surrounded by the electrically-insulating layer 10. The bottom portion of the electrically-insulating layer 10 is directly in contact with the heat-dissipation layer 40. The differences between the present embodiment and other embodiments are described as above, and the similarities therebetween will not be reiterated herein.

### Beneficial Effects of the Embodiments

In conclusion, in the insulating metal substrate structure provided by the present disclosure, by virtue of “the electrically-insulating layer 10 surrounding the plurality of metal layers 20 such that the plurality of metal layers 20 are separated into different regions to form the predetermined circuit pattern, and the electrically-insulating layer 10 having at least one recessed corner structure 101 that is configured to position the electrically-insulating heat-conductive layers 30 filled between one of the metal layers 20 and the heat-dissipation layer 40”, the plurality of metal layers can be quickly separated into different regions by the electrically-insulating layer to form the predetermined circuit pattern. In this way, the difficulty of a manufacturing process and a manufacturing cost are reduced, and the electrically-insulating heat-conductive layers filled between one of the metal layers and the heat-dissipation layer can be effectively fixed in position.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An insulating metal substrate structure, comprising:
an electrically-insulating layer;
a plurality of metal layers;
a plurality of electrically-insulating heat-conductive layers; and
a heat-dissipation layer;
wherein the plurality of electrically-insulating heat-conductive layers are formed on the heat-dissipation layer, the electrically-insulating layer surrounds the plurality of metal layers, such that the plurality of metal layers are separated into different regions to form a predetermined circuit pattern, and the electrically-insulating layer has at least one recessed corner structure that is configured to position the electrically-insulating heat-conductive layers filled between one of the metal layers and the heat-dissipation layer.

2. The insulating metal substrate structure according to claim 1, wherein the electrically-insulating layer is made from a polymer material having a high bonding property.

3. The insulating metal substrate structure according to claim 1, wherein each of the electrically-insulating heat-conductive layers is made from a polymer material having a high bonding property, and each of the electrically-insulating heat-conductive layers includes a ceramic filler.

4. The insulating metal substrate structure according to claim 1, wherein a thickness of each of the metal layers is less than a thickness of the electrically-insulating layer.

5. The insulating metal substrate structure according to claim 4, wherein each of the metal layers is a copper block having a thickness within a range from 1 mm to 5 mm.

6. The insulating metal substrate structure according to claim 1, wherein the heat-dissipation layer is a metal substrate for heat dissipation.

7. The insulating metal substrate structure according to claim 1, wherein the heat-dissipation layer is a ceramic substrate for heat dissipation and insulation.

8. The insulating metal substrate structure according to claim 1, wherein a bottom portion of the electrically-insulating layer is not in contact with the heat-dissipation layer.

9. The insulating metal substrate structure according to claim 1, wherein a bottom portion of the electrically-insulating layer is directly in contact with the heat-dissipation layer.
